(19) United States
(12) Patent Application Publication
(10) Pub. No.: US 2013/0095741 A1
(43) Pub. Date: Apr. 18, 2013

(54) ROOM OF CLOUD OPERATING SYSTEM

(71) Applicant: Feng-Chi YANG, Tu-Cheng (TW)

(72) Inventor: Feng-Chi YANG, Tu-Cheng (TW)

(73) Assignee: HON HAI PRECISION INDUSTRY CO., LTD., Tu-Cheng (TW)

(21) Appl. No.: 13/371,620

(22) Filed: Feb. 13, 2012

(30) Foreign Application Priority Data
Oct. 13, 2011 (CN) 201110309707.7

(51) Int. Cl. H05K 5/02

(52) U.S. Cl. 454/184

(57) ABSTRACT

A room of a cloud operating system includes a container defining a chamber, an airflow cover, a hot air dissipating device and a fan. The airflow cover is fixed in the chamber and defining a receiving space for accommodating an electronic component. The hot air dissipating device communicates the receiving space with exterior atmosphere. An airflow channel defined between the container and the airflow cover. The airflow channel communicates the receiving space with the hot air dissipating device. The fan is fixed in the airflow channel, the fan draw hot air generated by the electronic device in the receiving space to the airflow channel, and then exhausting out of the room by the hot air dissipating device.

### BACKGROUND

1. Technical Field

The disclosure generally relates to rooms containing cloud operating systems, particularly to such a room made from cargo container.

2. Description of Related Art

To quickly establish a cloud operating system, cargo container is typically used to act as a room of the cloud operating system. However, the container is located outside a building all the time so the container acting as the room of the cloud operating system may easily overheat due to the outside temperature around the container, affecting the operation and lifetime of the cloud operating system.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the exemplary room of a cloud operating system. Moreover, in the drawings like reference numerals designate corresponding parts throughout the several views. Wherever possible, the same reference numbers are used throughout the drawings to refer to the same or like elements of an embodiment.

FIG. 1 is a schematic view of an embodiment of a room of a cloud operating system.

FIG. 2 is a cross sectional view of the room in FIG. 1 along a line of II-II in a first state.

FIG. 3 is a cross sectional view of the room in FIG. 1 along a line of III-III.

FIG. 4 is a cross sectional view of the room in FIG. 1.

FIG. 5 is similar to FIG. 2, but showing the room in a second state.

### DETAILED DESCRIPTION

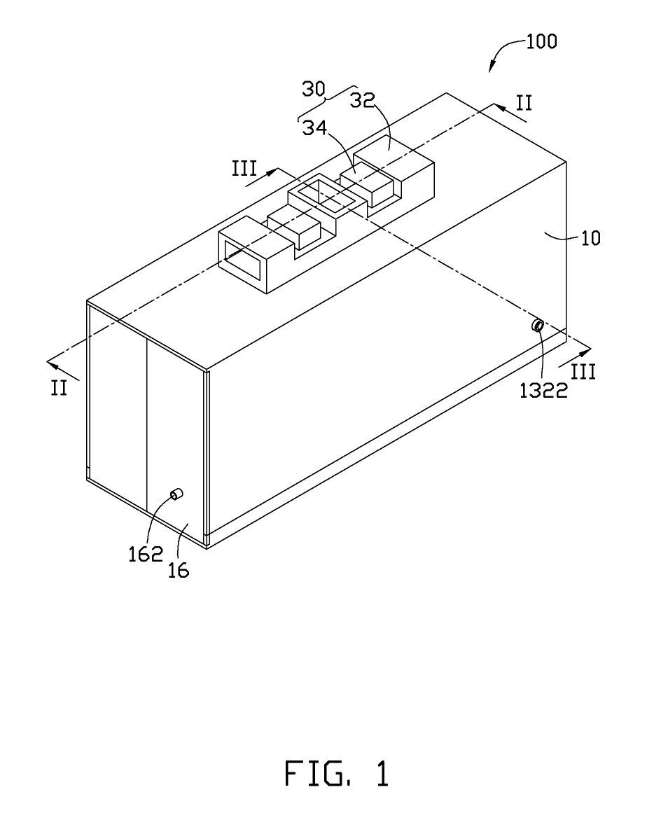

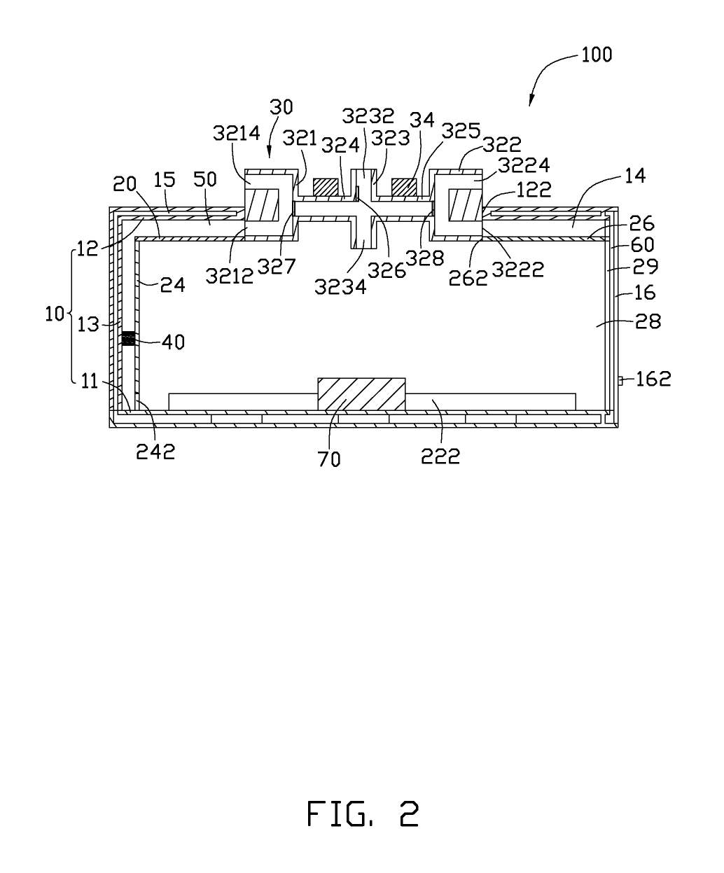

Referring to FIGS. 1 and 2, a room 100 of a cloud operating system includes a container 10, an airflow cover 20, a hot air dissipating device 30 and a plurality of fans 40.

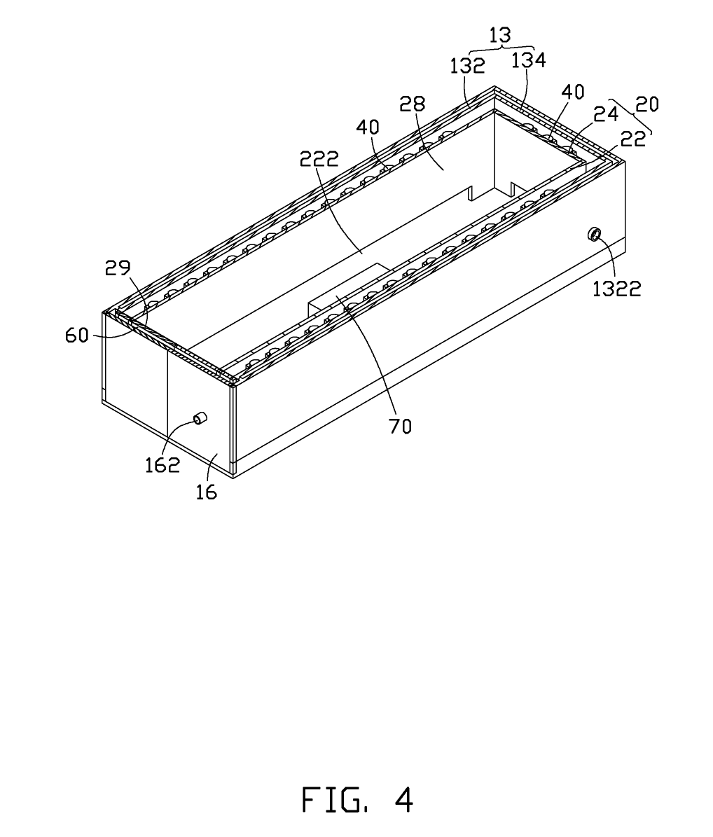

Referring to FIGS. 2 and 4, the container 10 includes a lower board 11, an upper board 12 opposite to the lower board 11, and a peripheral board 13 connecting the lower board 11 and the upper board 12. The lower board 11, upper board 12 and peripheral board 13 cooperatively form a chamber 14, in which the airflow cover 20 is received. The container 10 further defines a vacuum insulating compartment 15, by which the chamber 14 is surrounded, to protect the chamber 14 from the hot air outside the container 10. The upper board 12 defines a mounting hole 122 for mounting the hot air dissipating device 30. The peripheral board 13 includes two opposite sidewalls 132 and an end wall 134 connecting the sidewalls 132. To pump the vacuum insulating compartment 15, the container 10 defines a first vacuum valve 1322 communicating with the vacuum insulating compartment 15. In this exemplary embodiment, the first vacuum valve 1322 is defined in one of the sidewalls 132.

The container 10 further includes at least one first door 16, e.g., two first doors 16 in this exemplary embodiment. Each first door 16 is hinged to one of the sidewall 132 opposite to the end wall 134. A second vacuum valve 162 is defined in one of the first doors 16 to pump the vacuum insulating compartment 15.

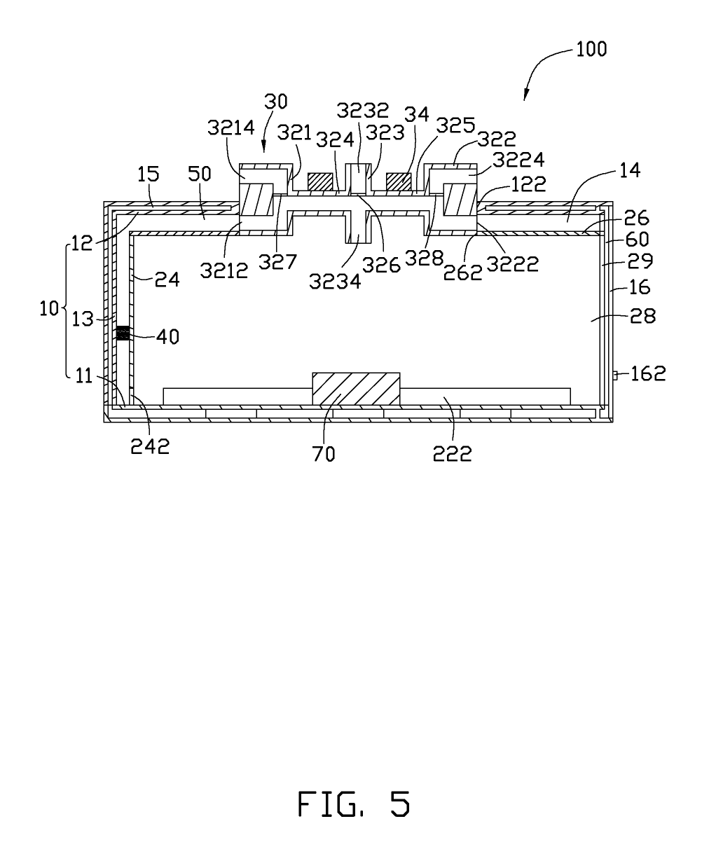

An airflow channel 50 is defined between the airflow cover 20 and container 10, to guide the hot air in the airflow cover 20 to the hot air dissipating device 30. The airflow cover 20 includes two side panels 22 (FIG. 4), an end panel 24 connecting the side panels 22, and an upper panel 26 (referring to FIG. 5) connecting the side panels 22 and the end panel 24. The side panels 22, end panel 24 and upper panel 26 cooperatively form a receiving space 28 for accommodating an electronic component 70 (FIG. 4), such as a server. In this exemplary embodiment, the side panels 22 are parallel to the sidewalls 132, the end panel 24 is parallel to the end wall 134, the upper panel 26 is parallel to the upper board 12, the airflow channel 50 is formed between the side panels 22, sidewalls 132, end panel 24, end wall 134, upper panel 26 and upper board 12.

The side panels 22 and the end panel 24 are all fixed to the lower board 11. Each side panel 22 defines a first exhausting hole 222. The end panel 24 defines a second exhausting hole 242. The first exhausting holes 222 and the second exhausting hole 242 are used to draw the hot air generated by the electronic components in the receiving space 28 to the airflow channel 50. The upper panel 26 defines a passage 262 connecting to the hot air dissipating device 30.

The airflow cover 20 further includes at least one second door 29, e.g., two second doors 29 in this exemplary embodiment. The second doors are hinged to distal ends of the side panels 22 far away from the end panel 24. After the first doors 16 and the second doors 29 are all closed, an enclosed space 60 is formed between the first doors 16 and the second doors 29. The enclosed space 60 can be pumped to a vacuum space by drawing of the second vacuum valve 162, to protect the chamber 14 from the hot air outside the container 10.

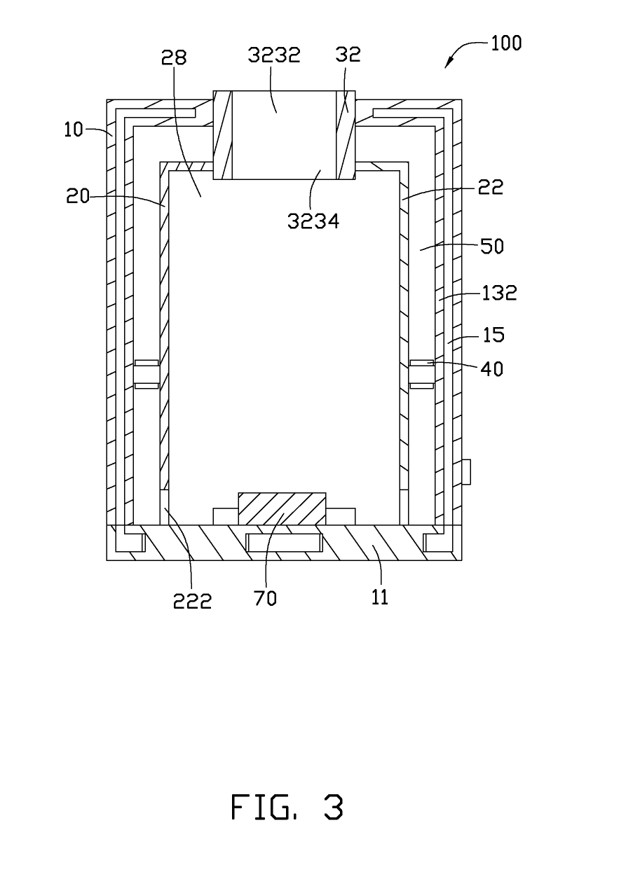

Referring to FIGS. 2 and 3, the hot air dissipating device 30 includes an exhausting element 32 and two cooling elements 34. The exhausting element 32 includes a first exhausting tube 321, a second exhausting tube 322 spaced from the first exhausting tube 321, a third exhausting tube 323 between the first exhausting tube 321 and the second exhausting tube 322, a first connecting tube 324 connecting the first exhausting tube 321 with the third exhausting tube 323, and a second connecting tube 325 connecting the second exhausting tube 322 with the third exhausting tube 323. One of the cooling elements 34 is fixed to the first connecting tube 324 to cool the hot air passing through the first connecting tube 324, the other cooling element 34 is fixed to the second connecting tube 325 to cool the hot air passing through the second connecting tube 325.

The first exhausting tube 321 includes a first airflow inlet 3212 and a first airflow outlet 3214. The second exhausting tube 322 includes a second airflow inlet 3222 and a second airflow outlet 3224. The third exhausting tube 323 includes a third airflow inlet 3232 and a third airflow outlet 3234. The first airflow inlet 3212 and the second airflow inlet 3222 both communicate the airflow channel 50. The first airflow outlet 3214, second airflow outlet 3224, the third airflow inlet 3232 all communicate with the exterior atmosphere. The third airflow outlet 3234 communicates with the receiving space 28.

The exhausting element 32 further includes a first gate valve 326, a second gate valve 327 and a third gate valve 328. The first gate valve 326 is located in the third exhausting tube 323 adjacent to the third airflow inlet 3232 to open or close the third airflow inlet 3232. The second gate valve 327 is located an end of the first connecting tube 324 adjacent to the first exhausting tube 321 to alternatively open/close the first airflow outlet 3214 or the first connecting tube 324. The third gate valve 328 is located an end of the second connecting tube 325 adjacent to the second exhausting tube 322 to alternatively open/close the second airflow outlet 3224 or the second connecting tube 325.

Referring to FIG. 3, the fans 40 is fixed to an inner surface of one of the sidewalls 132. The fans 40 draw the hot air generated by the electronic components in the receiving space 28 to the airflow channel 50 through the first exhausting holes 222 and the second exhausting hole 242.

One of the ways for exhausting the hot air in the receiving space 28 is: the first gate valve 326 is opened to make the third exhausting tube 323 communicate with the receiving space 28. The second gate valve 327 closes the first connecting tube 324, and the third gate valve 328 closes the second connecting tube 325. The fans 40 draw the hot air in the receiving space 28 to the airflow channel 50 through the first exhausting holes 222 and the second exhausting hole 242, the hot air in the airflow channel 50 then passes through the first exhausting tube 321 and the second exhausting tube 322 so the hot air is drawn out of the receiving space 28. At the same time, the fans 40 draw exterior cool air into the receiving space 28 through the third exhausting tube 323 and force the exterior cool air passing the electronic component 70 which is cooled.

Another way of exhausting the hot air in the receiving space 28 is: the first gate valve 326 closes the third exhausting tube 323. The second gate valve 327 closes the first exhausting tube 321, and the third gate valve 328 closes the second exhausting tube 322. The fans 40 draw the hot air in the receiving space 28 to the airflow channel 50 through the first exhausting holes 222 and the second exhausting hole 242, and then the hot air flows into the first connecting tube 324 and the second exhausting tube 322 accordingly through the first airflow inlet 3212 and the second airflow inlet 3222. The cooling elements cool the hot air in the first connecting tube 324 and the second connecting tube 325. After that, cooled air flows into the receiving space 28 through the third exhausting tube 323 to cool the electronic component 70.

In above exemplary embodiment, the fans 40 draw the hot air in the receiving space 28 out of the receiving space 28 through the airflow channel 50. Additionally, the vacuum insulating compartment 15, with which the receiving space 28 is surrounded, to protect the receiving space 28 from the hot air outside the container 10.

It is to be understood, however, that even through numerous characteristics and advantages of the disclosure have been set forth in the foregoing description, together with details of the system and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A room for containing a cloud operating system, the room comprising:
a container defining a chamber;
an airflow cover fixed in the chamber and defining a receiving space for accommodating an electronic component;
a hot air dissipating device communicating the receiving space with exterior atmosphere;
an airflow channel defined between the container and the airflow cover, the airflow channel communicating the receiving space with the hot air dissipating device
a fan fixed in the airflow channel, the fan drawing hot air generated by the electronic device in the receiving space to the airflow channel, and then exhausting the hot air out of the room by the hot air dissipating device.

2. The room as claimed in claim 1, wherein the container includes a lower board, an upper board, two opposite sidewalls and an end wall connecting the sidewalls, the sidewalls and the end wall all connect the lower board with the upper board; the lower board, upper board, sidewalls and the end wall cooperatively form the chamber.

3. The room as claimed in claim 2, wherein the container defines a vacuum insulating compartment surrounding the chamber.

4. The room as claimed in claim 3, wherein the container further includes a first vacuum valve defined in one of the sidewalls pumping the vacuum insulating compartment.

5. The room as claimed in claim 2, wherein the airflow cover includes two side panels, an end panel connecting the side panels, and an upper panel connecting the side panels and the end panel; the side panels, end panel and upper panel cooperatively form the receiving space.

6. The room as claimed in claim 5, wherein the side panels are parallel to the sidewalls, the end panel is parallel to the end wall, the upper panel is parallel to the upper board, the airflow channel is formed between the side panels, sidewalls, end panel, end wall, upper panel and upper board.

7. The room as claimed in claim 6, wherein the container further includes a first door opposite to the end wall, the first door is hinged to an end of one of the sidewalls far away from the end wall.

8. The room as claimed in claim 7, wherein the airflow cover further includes a second door hinged to a distal end of one of the side panels far away from the end panel; after the first door and the second door are closed, an enclosed space is formed between the first door and the second door.

9. The room as claimed in claim 8, wherein a second vacuum valve defined in the first door to pump the enclosed space to protect the chamber from the hot air outside the container.

10. The room as claimed in claim 1, wherein the hot air dissipating device includes an exhausting element comprising a first exhausting tube, a second exhausting tube spaced from the first exhausting tube; the hot air in the airflow channel is exhausted through the first exhausting tube and the second exhausting tube.

11. The room as claimed in claim 10, wherein the first exhausting tube includes a first airflow inlet and a first airflow outlet; the second exhausting tube includes a second airflow inlet and a second airflow outlet; the first airflow inlet and the second airflow inlet both communicate the airflow channel; the first airflow outlet and the second airflow outlet both communicate exterior atmosphere.

12. The room as claimed in claim 10, wherein the hot air dissipating further includes a third exhausting tube connecting the receiving space to the exterior atmosphere; the fan draw exterior cool air into the receiving space through the third exhausting tube and force the exterior cool air passing and cooling the electronic component.

13. A room for containing a cloud operating system, the room comprising:
a container defining a chamber;
an airflow cover fixed in the chamber and defining a receiving space for accommodating an electronic component;
a hot air dissipating device communicating with the receiving space;
an airflow channel defined between the container and the airflow cover, the airflow channel communicating the receiving space with the hot air dissipating device
a fan fixed in the airflow channel, the fan drawing hot air generated by the electronic device in the receiving space to the airflow channel.
wherein after the hot air in the airflow channel flow into and be cooled by the hot air dissipating device, the cooled air cooled by the hot air dissipating device is forced to flow into the receiving space again, thereby cooling the electronic component.

14. The room as claimed in claim 13, wherein the container includes a lower board, an upper board, two opposite sidewalls and an end wall connecting the sidewalls, the sidewalls and the end wall all connect the lower board with the upper board; the lower board, upper board, sidewalls and the end wall cooperatively form the chamber.

15. The room as claimed in claim 14, wherein the container defines a vacuum insulating compartment surrounding the chamber.

16. The room as claimed in claim 15, wherein the container further includes a first vacuum valve defined in one of the sidewalls pumping the vacuum insulating compartment.

17. The room as claimed in claim 14, wherein the airflow cover includes two side panels, an end panel connecting the side panels, and an upper panel connecting the side panels and the end panel; the side panels, end panel and upper panel cooperatively form the receiving space.

18. The room as claimed in claim 17, wherein the side panels are parallel to the sidewalls, the end panel is parallel to the end wall, the upper panel is parallel to the upper board, the airflow channel is formed between the side panels, sidewalls, end panel, end wall, upper panel and upper board.

19. The room as claimed in claim 18, wherein the container further includes a first door opposite to the end wall, the first door is hinged to an end of one of the sidewalls far away from the end wall.

20. The room as claimed in claim 13, wherein the hot air dissipating device includes a exhausting tube, a connecting tube connecting the airflow channel with the exhausting tube to guide the hot air from the airflow channel to the exhausting tube, a cooling element fixed to the connecting tube to cool the hot air passing through the connecting tube, the cooled air cooled by the cooling element is forced to flow into the receiving space.
